(19) United States
(12) Patent Application Publication
(10) Pub. No.: US 2003/0008070 A1
(43) Pub. Date: Jan. 9, 2003

(54) Low-resistivity tungsten from high-pressure chemical vapor deposition using metal-organic precursor

(75) Inventors: Sean Michael Seutter, San Jose, CA (US); Seshadri Ganguli, Sunnyvale, CA (US); Mei Chang, Saratoga, CA (US); Michael X. Yang, Palo Alto, CA (US); Ming Xi, Milpitas, CA (US)

Correspondence Address: APPLIED MATERIALS, INC., 2881 SCOTT BLVD. M/S 2061, SANTA CLARA, CA, 95050, US

(73) Assignee: Applied Materials,Inc

(21) Appl. No.: 09/880,465

(22) Filed: Jun. 12, 2001

(51) Int. Cl. C23C 16/00

(52) U.S. Cl. 427/255.28; 427/250

(57) ABSTRACT

Provided herein is a method of depositing a low resistivity tungsten film onto a wafer comprising the steps of introducing a metalorganic tungsten-containing compound into a deposition chamber of a CVD apparatus; maintaining the deposition chamber at a pressure and the wafer at a temperature suitable for the high pressure chemical vapor deposition of the tungsten film onto the wafer; thermally decomposing the tungsten-containing compound in the deposition chamber; and vapor-depositing the tungsten film onto the wafer thereby forming a low-resistivity tungsten film. Specifically provided is a method of depositing a low-resistivity tungsten film by high pressure MOCVD using tungsten hexacarbonyl as the precursor. Also provided is a low-resistivity tungsten film.

### BACKGROUND OF THE INVENTION

1. Field of the Invention

The present invention relates generally to the field of semiconductor manufacturing. More specifically, the present invention relates to a method of depositing low-resistivity tungsten films by high pressure chemical vapor deposition.

2. Description of the Related Art

With the current trend toward fabrication of VLSI and ULSI devices, it is necessary to be able to deposit thin metal films on or into the scaled down features in these semiconductor devices. The effectiveness of a metal system is determined by the resistivity, length, thickness, and total contact resistance of the metal-wafer interconnects. Refractory metals such as titanium, tantalum, molybdenum and tungsten offer lower contact resistance; tungsten with its low resistivity is perhaps the most deposited metal.

Currently a low-pressure process is used for depositing thin-films of alpha-phase tungsten. The low-pressure process alpha-tungsten thin-films are obtained by a low-pressure CVD process using a metal organic precursor such as solid tungsten hexacarbonyl (W(CO)₆). Deposition of tungsten occurs by the thermal decomposition of W(CO)₆ on a wafer surface, a pyrolytic reaction. Alpha-phase W is produced for wafer temperatures greater than about 375° C.

While tungsten's lower resistivity and contact resistance offer advantages for its use as a metal conducting film, impurities, such as carbon and oxygen that increase resistivity and deposition uniformity problems, need to be avoided during deposition. Carbon monoxide (CO) is a by-product of the pyrolytic reaction of W(CO)₆, and to minimize the incorporation of impurities during deposition, the chamber is pumped by a turbo pump, that provides a higher pumping speed relative to common mechanical pumps.

However, since the deposition of alpha-W is at low pressure (<100 mTorr), the wafer temperature is very sensitive to pressure changes. FIG. 1 shows that the wafer temperature increases 8° C. for a pressure change from 38 to 55 mTorr which potentially could correspond to an increase of 20 μΩ-cm in film resistivity. This high sensitivity is a challenge in developing a production worthy process, and is motivation for investigating a higher pressure process. Thus a method of high pressure CVD applications that stablilizes wafer temperature sensitivity to low pressure fluctuations and increases throughput while concomitantly yielding a low resistivity tungsten film with minimal incorporation of impurities would be beneficial.

Therefore, the prior art is deficient in the lack of effective means of depositing tungsten films using a high pressure process. Specifically, the prior art is deficient in the lack of effective means of depositing a low-resistivity tungsten film by high pressure MOCVD. The present invention fulfills these long-standing needs and desires in the art.

### SUMMARY OF THE INVENTION

In one embodiment of the present invention there is provided a method of depositing a low resistivity tungsten film onto a wafer comprising the steps of introducing a metalorganic tungsten-containing compound into a deposition chamber of a CVD apparatus; maintaining the deposition chamber at a pressure and the wafer at a temperature suitable for the high pressure chemical vapor deposition of the tungsten film onto the wafer; thermally decomposing the tungsten-containing compound in the deposition chamber; and vapor-depositing the tungsten film onto the wafer thereby forming a low-resistivity tungsten film.

In another embodiment of the present invention there is provided a method of depositing a low resistivity tungsten film onto a wafer comprising the steps of subliming the metalorganic tungsten-containing compound to a gaseous phase; stabilizing the flow of the tungsten-containing gas; mixing the tungsten-containing gas with a carrier gas; flowing the tungsten-containing/carrier gas mixture to the deposition chamber; maintaining the deposition chamber at a pressure and the wafer at a temperature suitable for the high pressure chemical vapor deposition of the tungsten film onto the wafer; thermally decomposing the tungsten-containing compound in the deposition chamber; and vapor-depositing the tungsten film onto the wafer thereby forming a low-resistivity tungsten film.

In yet another embodiment of the present invention there is provided a method of depositing a low resistivity tungsten film onto a wafer comprising the steps of subliming tungsten hexacarbonyl to a gaseous phase at about 75° C.; stabilizing the flow of the tungsten hexacarbonyl gas; mixing the tungsten hexacarbonyl gas with a carrier gas; flowing the tungsten hexacarbonyl/carrier gas mixture into a deposition chamber of a CVD apparatus; maintaining the deposition chamber at a pressure from about 0.1 Torr to about 20 Torr and the wafer at a temperature from 200° C. to about 500° C. wherein these conditions are suitable for the high pressure chemical vapor deposition of the tungsten film onto the wafer; thermally decomposing the tungsten-containing gas in the deposition chamber; and vapor-depositing the tungsten film onto the wafer thereby forming a low-resistivity tungsten film.

Other and further aspects, features, and advantages of the present invention will be apparent from the following description of the embodiments of the invention given for the purpose of disclosure.

### BRIEF DESCRIPTION OF THE DRAWINGS

So that the matter in which the above-recited features, advantages and objects of the invention, as well as others which will become clear, are attained and can be understood in detail, more particular descriptions of the invention briefly summarized above may be had by reference to certain embodiments thereof which are illustrated in the appended drawings. These drawings form a part of the specification. It is to be noted, however, that the appended drawings illustrate embodiments of the invention and therefore are not to be considered limiting in their scope.

FIG. 1 shows the relationship between wafer temperature and chamber pressure.

FIG. 2 shows the AES depth profiles of an LP α-W process (FIG. 2A) and a HP α-W process (FIG. 2B).

FIG. 3 shows the SIMS depth profiles of an LP α-W process (FIG. 3A) and a HP α-W process (FIG. 3B).

FIG. 4 shows the XRD 2-theta scans of an LP α-W process (FIG. 4A) and a HP α-W process (FIG. 4B).

FIG. 5 shows a SEM surface view and a TEM cross-section of an LP α-W process (FIG. 5A) and of a HP α-W process (FIG. 5B).

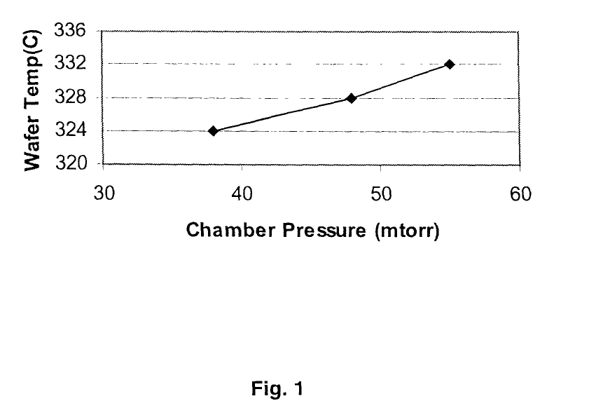

### DETAILED DESCRIPTION OF THE INVENTION

In one embodiment of the present invention there is provided a method of depositing a low resistivity tungsten film onto a wafer comprising the steps of introducing a metalorganic tungsten-containing compound into a deposition chamber of a CVD apparatus; maintaining the deposition chamber at a pressure and the wafer at a temperature suitable for the high pressure chemical vapor deposition of the tungsten film onto the wafer; thermally decomposing the tungsten-containing compound in the deposition chamber; and vapor-depositing the tungsten film onto the wafer thereby forming a low-resistivity tungsten film.

In an aspect of this embodiment there is provided a method of introducing the metalorganic tungsten-containing compound into the deposition chamber of a CVD apparatus comprising the steps of subliming the metalorganic tungsten-containing compound to a gaseous phase; stabilizing the flow of the tungsten-containing gas; mixing the tungsten-containing gas with a carrier gas; flowing the tungsten-containing/carrier gas mixture to the deposition chamber.

The metalorganic tungsten-containing compound can be generally of the formula Wx(CO)y. A representative example is tungsten hexacarbony (W(CO)₆). Suitable conditions for a high pressure MOCVD process are a chamber pressure from about 0.1 Torr to about 20 Torr and a wafer temperature from about 200° C. to about 500° C. An example of a sublimation temperature is 75° C. The tungsten films deposited herein have resistivities less than about 30 micro-ohm centimeters. A representative range is from about 10 micro-ohm centimeters to about 20 micro-ohm centimeters.

In another embodiment of the present invention there is provided a method of depositing a low resistivity tungsten film onto a wafer comprising the steps of subliming the metalorganic tungsten-containing compound to a gaseous phase; stabilizing the flow of the tungsten-containing gas; mixing the tungsten-containing gas with a carrier gas; flowing the tungsten-containing/carrier gas mixture to the deposition chamber; maintaining the deposition chamber at a pressure and the wafer at a temperature suitable for the high pressure chemical vapor deposition of the tungsten film onto the wafer; thermally decomposing the tungsten-containing compound in the deposition chamber; and vapor-depositing the tungsten film onto the wafer thereby forming a low-resistivity tungsten film. The representative examples of specific aspects of this method are as disclosed supra.

In another embodiment of the present invention there is provided a method of depositing a low resistivity tungsten film onto a wafer comprising the steps of subliming tungsten hexacarbonyl to a gaseous phase at about 75° C.; stabilizing the flow of the tungsten hexacarbonyl gas; mixing the tungsten hexacarbonyl gas with a carrier gas; flowing the tungsten hexacarbonyl/carrier gas mixture into a deposition chamber of a CVD apparatus; maintaining the deposition chamber at a pressure from about 0.1 Torr to about 20 Torr and the wafer at a temperature from 200° C. to about 500° C. wherein these conditions are suitable for the high pressure chemical vapor deposition of the tungsten film onto the wafer; thermally decomposing the tungsten-containing gas in the deposition chamber; and vapor-depositing the tungsten film onto the wafer thereby forming a low-resistivity tungsten film. Representative examples of the carrier gas are argon, helium and nitrogen. A tungsten film deposited in this manner has a resistivity of less than about 30 micro-ohm centimeters with about 10 micro-ohm centimeters to about 20 micro-ohm centimeters being a representative range.

In yet another embodiment of the present invention there is provided a low-resistivity tungsten film deposited by the methods disclosed herein.

Provided herein is a method for the high-pressure (>0.1 Torr) deposition of tungsten films by MOCVD. Metal organic tungsten precursors having a formula Wx(CO)y can be used. Solid tungsten hexacarbonyl, W(CO)₆ is currently used as a precursor. W(CO)₆ sublimes at about 75° C. to produce a vapor pressure of about 1.8 Torr. Generally, exact sublimation temp depends on the desired vapor pressure and also may depend strongly on the composition of the precursor and any impurities.

The W(CO)₆ flow is controlled by a low vapor pressure mass-flow controller (MFC). The precursor supply lines include a dump line so they can be directly pumped. The W(CO)₆ ampoule and the MFC are both mounted to the top of a TxZ type CVD chamber lid W(CO)₆, the vapor formed after sublimation is mixed with a carrier gas such as argon gas in a “mixer” on top of the chamber downstream of the MFC, and the gas mixture then flows to the wafer in the deposition chamber. W(CO)₆ vapor may also be mixed with other inert gases such as helium or with nitrogen.

Deposition of tungsten occurs by the thermal decomposition of W(CO)₆ on a wafer surface, a pyrolytic reaction. Residual carrier gas and CO are released in the deposition reaction and pumped out of the chamber using a standard mechanical pump. The process conditions for the high pressure MOCVD of tungsten are listed below. Both the precursor and the carrier gas are flowed at a rate greater than 100 sccm.

Precursors: Wx(CO)y

Carrier gases: argon, helium, nitrogen

Chamber pressure: 0.1 Torr<P<20 Torr

Wafer temperature: 200° C.<T<500° C.

The motivation for the prior low-pressure process was to prevent incorporation of impurities by pumping out carbon monoxide (CO), a by-product of the pyrolytic reaction of tungsten hexacarbonyl, with a turbo pump. Carbon and oxygen that incorporate into the tungsten film may increase resistivity of the film. For this high pressure process, the turbo pump is not used and the chamber is pumped only by a mechanical pump. It is also demonstrated herein that the grain structure in the nucleation layer of the tungsten film is more crucial than deposition pressure in obtaining low-resistivity tungsten films. Low-resistivity tungsten is more desirable to reduce contact resistance in electrical devices.

Another advantage of the high-pressure process is the reduced sensitivity of the wafer to changes in emissivity of inside chamber surfaces. Higher pressures will increase heat conduction from heater to wafer. This makes the actual wafer temperature more stable and less sensitive to deposition on inside chamber surfaces. Finally, with a high pressure process, the wafer temperature will also be less sensitive to fluctuations in chamber pressure.

The following examples are given for the purpose of illustrating various embodiments of the invention and are not meant to limit the present invention in any fashion.

### EXAMPLE 1

Comparison: Process Conditions and Resistivity

Table 1 compares process conditions, thickness, resistivity, and 49-point uniformity of sheet resistance for the low-pressure (LP) process and the high-pressure (HP) process. The heater temperature was 480° C. for both the low-pressure and high-pressure experiments. A very low resistivity was obtained with the high-pressure process. For a 723 Å thick film, the resistivity was only 12.1 μΩ-cm. In addition, even for a thickness of 417 Å, the resistivity is 13.9 μΩ-cm. The minimum resistivity ever achieved with the low-pressure process is so far only 40 μΩ-cm.

The low-pressure and high-pressure wafers described in Table 1 were run consecutively on the same day. The low-pressure process was run before the high-pressure process. For the high-pressure process the 723 Å film was run immediately prior to running the 417 Å film. It is noted that the deposition rate for the first high-pressure wafer is greater than the deposition rate for the second wafer. This can be attributed to the long pressurization time of the ampoule and precursor supply lines, which takes nearly 8 minutes for the MFC to reach a steady state after the precursor supply lines are used at low pressure. The deposition rate is repeatable after the ampoule and supply lines fully pressurize. The 723 Å high-pressure wafer (resistivity 12.1 μΩ-cm) and a low-pressure 1000 Å wafer (resistivity 78.6 μΩ-cm) are further analyzed by AES, SIMS, XRD, SEM, and TEM to determine why the HP process produces lower resistivity.

TABLE 1
Alpha-W: High vs. Low Pressure Process

| | P | Ar | | W(CO)₆ | Dep | Thick | resist | |
|---|---|---|---|---|---|---|---|---|
| | mT | sccm | pump | sccm | time | Å | μΩ-cm | unif |
| LP αW | 75 | 180 | turbo | 2.5 | 550 s | 970 | 50.0 | 16% |
| HP αW | 440 | 500 | TVO | 2.5 | 700 s | 723 | 12.1 | 20% |
| | 440 | 500 | TVO | 2.5 | 700 s | 417 | 13.9 | 20% |

### EXAMPLE 2

Comparison: Composition by AES

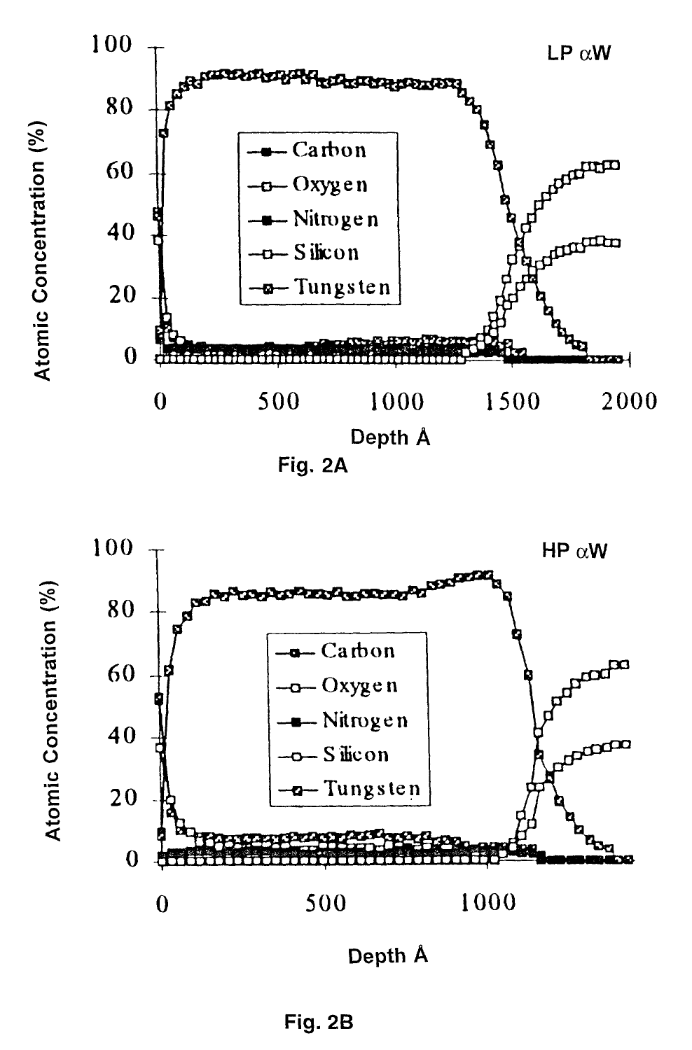

FIG. 2 shows an AES depth profile of a low resistivity wafer (12.1 μΩ-cm, thickness 723 Å) (FIG. 2B) produced by the high-pressure process, and an AES depth profile of a higher resistivity wafer (78.6 μΩ-cm, thickness 1000 Å) (FIG. 2A) produced by the low-pressure process. Oxygen and carbon are both lower in the low-pressure wafer.

### EXAMPLE 3

Comparison: Composition by SIMS

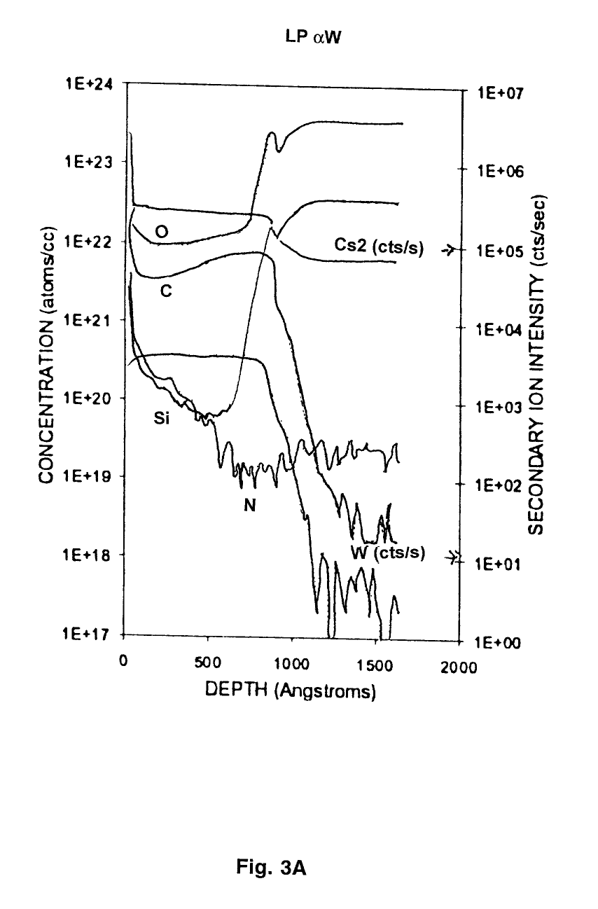

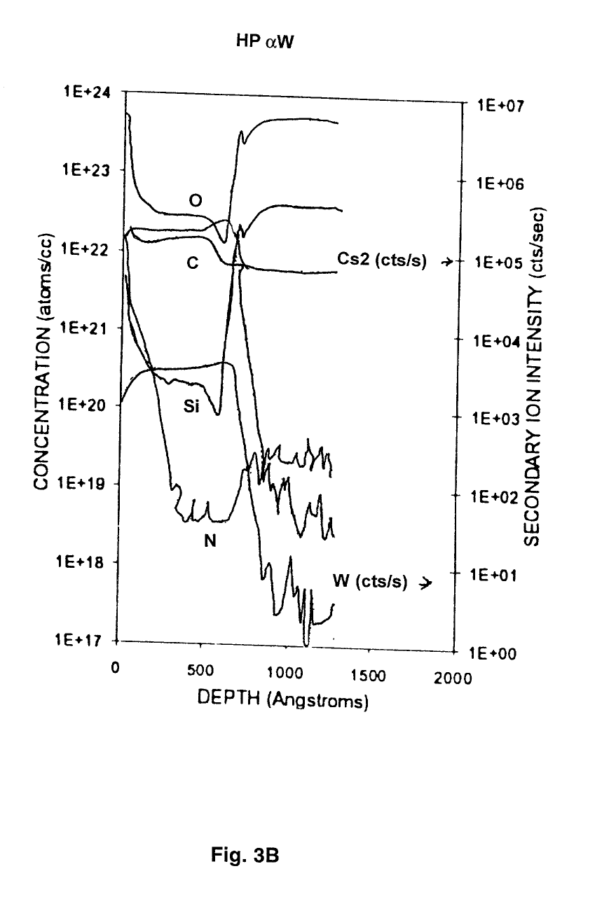

FIG. 3 shows a SIMS depth profile of a low resistivity wafer (12.1 μΩ-cm, thickness 723 Å) (FIG. 3B) produced by the high-pressure process, and a SIMS depth profile of a higher resistivity wafer (78.6 μΩ-cm, thickness 1000 Å) (FIG. 3A) produced by the low-pressure process. These are the same two wafers analyzed in Example 2. For most of the surface layer on the high-pressure wafer, the SIMS data verifies AES data, indicating that the oxygen and carbon concentrations are higher in the high-pressure wafer. Upon closer analysis, the oxygen and carbon both dip near the tungsten/SiO₂ interface for the high-pressure wafer, and the concentrations of the impurities near the interface are approximately equal to the measured concentrations in the low-pressure wafer. This was not observed in the AES scans.

### EXAMPLE 4

Comparison: Structure by XRD

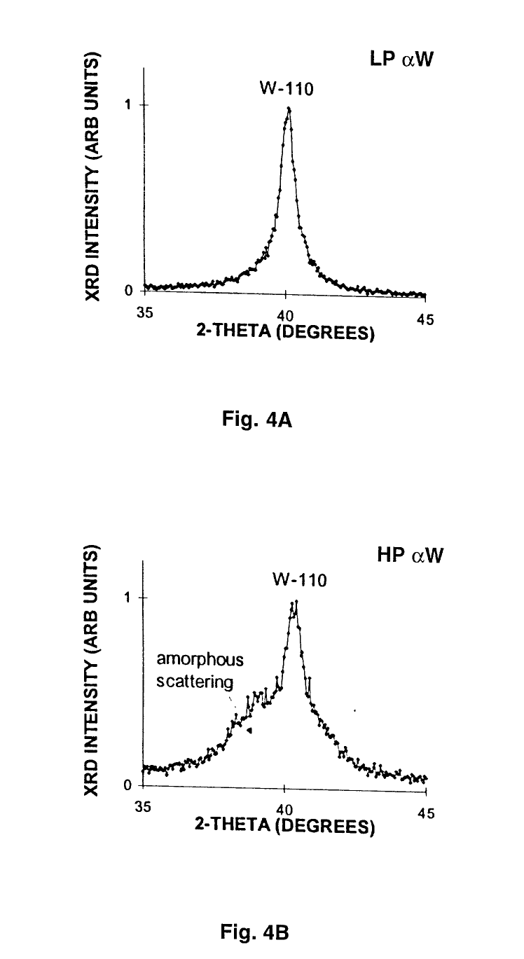

FIG. 4 shows an XRD 2-theta scan of a low resistivity wafer (12.1 μΩ-cm, thickness 723 Å) (FIG. 4B) produced by the high-pressure process, and an XRD 2-theta scan of a higher resistivity wafer (78.6 μΩ-cm, thickness 1000 Å) (FIG. 4A) produced by the LP process. These are the same two wafers analyzed in the previous two Examples. The XRD scan of the IP wafer shows pure alpha-phase tungsten with a peak at 40.3 degrees. The XRD scan of the high-pressure wafer shows mixed amorphous and alpha-phase.

### EXAMPLE 5

Comparison: Structure by SEM and TEM

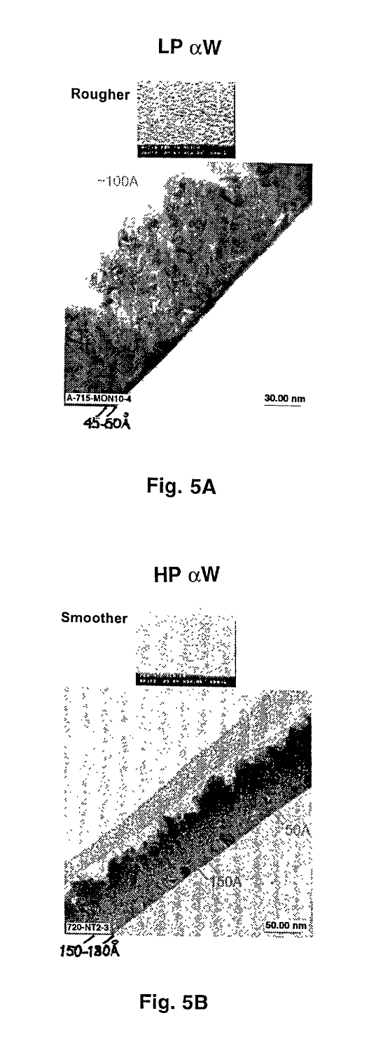

FIG. 5 shows an SEM surface view and a TEM cross-section of a low resistivity wafer (12.1 μΩ-cm, thickness 723 Å) (FIG. 5B) produced by the high-pressure process, and similar images are shown of a higher resistivity wafer (78.6 μΩ-cm, thickness 1000 Å) (FIG. 5A) produced by the low-pressure process. These are the same two wafers analyzed in the previous three examples. The SEM images show the surface of the high-pressure wafer is smoother than the low-pressure wafer. The TEM images show the high-pressure wafer has a thicker nucleation layer than the low-pressure wafer. Both have much thicker overlayers, and for both wafers, the interface between the nucleation layer and overlayer is surprisingly abrupt.

For the high-pressure wafer, the 150-180 Å thick nucleation layer has columnar grains 50-150 Å wide. For the low-pressure wafer, the 40-50 Å thick nucleation layer appears to have grains that are much smaller (<50 Å), and they do not appear columnar. For the high-pressure wafer, the overlayer has small spherical-like grains less than 50 Å, and many voids are seen at grain boundaries. For the low-pressure wafer, the overlayer has larger spherical-like grains about 100 Å, and maybe there are voids at grain boundaries. For the low-pressure wafer, some of the grains in the overlayer appear to have interference patterns, indicating a crystalline phase. This could indicate that for the high-pressure wafer, the nucleation layer is alpha-phase tungsten, and the overlayer contains amorphous and alpha-phase tungsten.

### EXAMPLE 6

Summary and Conclusions of LP vs. HP Processes

Table 2 outlines the conclusions from the AES, SIMS, XRD, SEM, and TEM analysis of wafers produced by the high pressure (HP) process versus the low pressure (LP) process. The resistivity appears to be much lower for the high pressure process since a thicker nucleation layer is produced with columnar grains. The oxygen and carbon concentrations of the nucleation layer in the high pressure wafer is similar to the concentrations in the low-pressure wafer, but actually the impurity concentrations in the overlayer of the high pressure wafer are greater than the impurity concentrations in the low-pressure wafer.

### TABLE 2

### Comparison of HP and LP Processes

High Pressure Process

Low resistivity: 12 μΩ-cm (723 Å); 13.9 μΩ-cm (417 Å)

Composition: C & O 5-10%; less in nucleation layer

Structure:

XRD: alpha-phase+amorphous

TEM: nucleation layer

Uniform, 150-180 Å thick

Columnar grains, 50-150 Å wide

overlayer:

small, spherical grains <50 Å

many voids at grain boundaries

smoother surface

conclusion: nucleation layer=alpha-phase

overlayer=alpha-phase mixed w/amorphous

Low Pressure Process

Resistivity: >40 μΩ-cm (1000 Å)

Composition: C & O <5%

Structure:

XRD: alpha-phase

TEM: nucleation layer

Uniform, 40-50 Å thick

maybe <50 Å grains, not clear

overlayer:

˜100 A spherical, crystalline grains

maybe voids at grain boundaries

rougher surface

### EXAMPLE 7

Alternative Tungsten HP MOCVD Systems

It is contemplated that modified and/or alternative delivery processes and configurations can be used to deposit tungsten films by HP MOCVD. Although in the current delivery system the mass-flow controller stabilizes the sublimed W(CO)₆ relatively reliably and accurately, the apparatus itself is heavy, bulky and complicated. The delivery system can have cold spots that condense the precursor that can periodically clog the lines and cause leak-by in the pneumatic valves. In alternative designs the MFC and the ampoule may be mounted below the CVD apparatus or may be remote from the apparatus.

Also, it is further contemplated that precursors for the HP MOCVD of alpha-phase tungsten are not limited to tungsten hexacarbonyl and may encompass other suitable metalorganic tungsten carbonyl precursors as disclosed herein. The pressure required for HP MOCVD of alpha-phase tungsten may be a high pressure which, with a suitable metalorganic precursor, yields a low resistivity, low impurity alpha phase tungsten film the characteristics of which are at least as beneficial as those disclosed herein.

Tungsten is considered a good candidate for a barrier layer to prevent Cu diffusion/mixing. Low-resistivity tungsten is even more desirable to reduce contact resistance in electrical devices. The high pressure alpha-phase tungsten deposited herein could provide an excellent barrier layer to copper films for today's scaled down devices with high aspect ratio contacts and vias.

One skilled in the art will readily appreciate that the present invention is well adapted to carry out the objects and obtain the ends and advantages mentioned, as well as those inherent therein. It will be apparent to those skilled in the art that various modifications and variations can be made in practicing the present invention without departing from the spirit or scope of the invention. Changes therein and other uses will occur to those skilled in the art which are encompassed within the spirit of the invention as defined by the scope of the claims.

What is claimed is:

1. A method of depositing a low resistivity tungsten film onto a wafer comprising the steps of:
(a) introducing a metalorganic tungsten-containing compound into a deposition chamber of a CVD apparatus;
(b) maintaining the deposition chamber at a pressure and the wafer at a temperature suitable for the high pressure chemical vapor deposition of the tungsten film onto the wafer;
(c) thermally decomposing the tungsten-containing compound in the deposition chamber; and
(d) vapor-depositing the tungsten film onto the wafer thereby forming a low-resistivity tungsten film.

2. The method of claim 1, wherein the introduction of the metalorganic tungsten-containing compound into the deposition chamber of a CVD apparatus comprises the steps of:
(a) subliming the metalorganic tungsten-containing compound to a gaseous phase;
(b) stabilizing the flow of the tungsten-containing gas;
(c) mixing the tungsten-containing gas with a carrier gas; and
(d) flowing the tungsten-containing/carrier gas mixture to the deposition chamber.

3. The method of claim 2, wherein the sublimation occurs at about 75° C.

4. The method of claim 2, wherein the carrier gas is argon, helium or nitrogen.

5. The method of claim 1, wherein the metalorganic tungsten-containing compound is a Wx(CO)y compound

6. The method of claim 5, wherein the compound is tungsten hexacarbonyl.

7. The method of claim 1, wherein the chamber pressure is from about 0.1 Torr to about 20 Torr.

8. The method of claim 1, wherein the wafer temperature is from about 200° C. to about 500° C.

9. The method of claim 1, wherein the resistivity of the tungsten film is less than about 30 micro-ohm centimeter.

10. The method of claim 9, wherein the resistivity of the tungsten film is from about 10 micro-ohm centimeters to about 20 micro-ohm centimeters.

11. A method of depositing a low resistivity tungsten film onto a wafer comprising the steps of:
(a) subliming the metalorganic tungsten-containing compound to a gaseous phase;
(b) stabilizing the flow of the tungsten-containing gas;
(c) mixing the tungsten-containing gas with a carrier gas;
(d) flowing the tungsten-containing/carrier gas mixture to the deposition chamber
(e) maintaining the deposition chamber at a pressure and the wafer at a temperature suitable for the high pressure chemical vapor deposition of the tungsten film onto the wafer; and
(f) thermally decomposing the tungsten-containing compound in the deposition chamber; and
(g) vapor-depositing the tungsten film onto the wafer thereby forming a low-resistivity tungsten film.

12. The method of claim 11, wherein the sublimation occurs at about 75° C.

13. The method of claim 11, wherein the carrier gas is argon, helium or nitrogen.

14. The method of claim 11, wherein the metalorganic tungsten-containing compound is a Wx(CO)y compound

15. The method of claim 14, wherein the compound is tungsten hexacarbonyl.

16. The method of claim 11, wherein the chamber pressure is from about 0.1 Torr to about 20 Torr.

17. The method of claim 11, wherein the wafer temperature is from about 200° C. to about 500° C.

18. The method of claim 11, wherein the resistivity of the tungsten film is less than about 30 micro-ohm centimeter.

19. The method of claim 18, wherein the resistivity of the tungsten film is from about 10 micro-ohm centimeters to about 20 micro-ohm centimeters.

20. A method of depositing a low resistivity tungsten film onto a wafer comprising the steps of:
(a) subliming tungsten hexacarbonyl to a gaseous phase at about 75° C.;
(b) stabilizing the flow of the tungsten hexacarbonyl gas;
(c) mixing the tungsten hexacarbonyl gas with a carrier gas;
(d) flowing the tungsten hexacarbonyl/carrier gas mixture into a deposition chamber of a CVD apparatus;
(e) maintaining the deposition chamber at a pressure from about 0.1 Torr to about 20 Torr and the wafer at a temperature from 200° C. to about 500° C. wherein these conditions are suitable for the high pressure chemical vapor deposition of the tungsten film onto the wafer;
(f) thermally decomposing the tungsten hexacarbonyl gas in the deposition chamber; and
(g) vapor-depositing the tungsten film onto the wafer thereby forming a low-resistivity tungsten film.

21. The method of claim 20, wherein the carrier gas is argon, helium or nitrogen.

22. The method of claim 20, wherein the resistivity of the tungsten film is less than about 30 micro-ohm centimeter.

23. The method of claim 22, wherein the resistivity of the tungsten film is from about 10 micro-ohm centimeters to about 20 micro-ohm centimeters.

24. A low-resistivity tungsten film formed by the method of claim 1.
